(19) United States
(12) Patent Application Publication
(10) Pub. No.: US 2026/0018423 A1
(43) Pub. Date: Jan. 15, 2026

(54) COMPOSITE COMPRISING GALLIUM NITRIDE AND DIAMOND AND PRODUCTION METHOD FOR SAME

(71) Applicant: NATIONAL INSTITUTE OF ADVANCED INDUSTRIAL SCIENCE AND TECHNOLOGY, Tokyo (JP)

(72) Inventors: Takashi MATSUMAE, Tsukuba-shi (JP); Yuuichi KURASHIMA, Tsukuba-shi (JP); Hideki TAKAGI, Tsukuba-shi (JP)

(21) Appl. No.: 19/332,144

(22) Filed: Sep. 18, 2025

Related U.S. Application Data
(63) Continuation of application No. PCT/JP2024/010253, filed on Mar. 15, 2024.

(30) Foreign Application Priority Data
Mar. 30, 2023 (JP) 2023-054478

(51) Int. Cl. H01L 21/48; B32B 9/00; B32B 9/04; B32B 37/18; B32B 38/00; C30B 29/04; C30B 29/40; C30B 29/68; C30B 33/00; H01L 23/373; H10D 62/85

(52) U.S. Cl. CPC H01L 21/481; B32B 9/007; B32B 9/04; B32B 37/18; C30B 29/04; C30B 29/406; C30B 29/68; C30B 33/005; H01L 23/3732; H10D 62/8503; B32B 2038/0052; B32B 2250/02; B32B 2310/0409; B32B 2313/04; B32B 2315/02; B32B 2457/14

(57) ABSTRACT

A composite that includes a gallium nitride layer; an intermediate layer that is formed on a surface of the gallium nitride layer and contains carbon, gallium, and oxygen; and a diamond layer that is joined to the surface of the gallium nitride layer through the intermediate layer.

### TECHNICAL FIELD

The present application relates to a composite in which gallium nitride and diamond are joined with an intermediate layer being interposed therebetween, where the intermediate layer contains carbon, gallium, and oxygen, and relates to a production method for the same.

### BACKGROUND ART

Gallium nitride (GaN) is attracting attention as a substrate material for next-generation power semiconductors. In addition, in order to improve the heat dissipation performance of GaN, a semiconductor device in which a GaN-based semiconductor is directly joined to a diamond substrate is known (Patent Document 1). In Patent Document 1, each of surfaces where GaN and diamond are to be joined is irradiated with an argon beam, a natural oxide film or the like is removed to activate the surfaces, and then the GaN and diamond are directly joined to each other in a vacuum container having a pressure of 10⁻⁶ Pa or less.

In the joining method of Patent Document 1, the crystallinity of GaN deteriorates due to the irradiation of the GaN surface with the argon beam. In a case where the crystallinity of GaN deteriorates, the characteristics of the GaN-based semiconductor device deteriorate. In addition, the irradiation of the diamond surface with the argon beam also deteriorates the crystallinity of the diamond. Diamond has a high dielectric breakdown electric field and thus is suitable for ensuring the insulation of GaN-based semiconductors. However, a diamond having deteriorated crystallinity has poor electrical insulating properties. Therefore, in a case where a diamond having deteriorated crystallinity is joined to a GaN-based semiconductor, it adversely affects the operation of the GaN-based semiconductor. In addition, the joining method of Patent Document 1 requires a vacuum joining device since it is carried out in a high vacuum.

### CITATION LIST

### Patent Document

[Patent Document 1] Japanese Unexamined Patent Application, First Publication No. 2021-13007

### SUMMARY

The composite according to the present application has a gallium nitride layer; an intermediate layer that is formed on a surface of the gallium nitride layer and contains carbon, gallium, and oxygen; and a diamond layer that is joined to the surface of the gallium nitride layer through the intermediate layer.

A production method for a composite according to one aspect of the present application includes a first base material treatment step of subjecting a surface of a gallium oxide layer of a first base material to one or more of an oxidation treatment, a nitridation treatment, and a reduction treatment to functionalize the surface of the gallium oxide layer, where the first base material includes a gallium nitride layer and the gallium oxide layer which is formed and exposed on the gallium nitride layer; a second base material treatment step of subjecting a surface of a diamond layer of a second base material to an oxidation treatment to functionalize the surface of the diamond layer, where the second base material includes the diamond layer, the surface of which is a (111) plane; and a joining step of applying reaction energy to a contact part to join the first base material and the second base material while the surface of the gallium oxide layer that has undergone the first base material treatment step and the surface of the diamond layer that has undergone the second base material treatment step are in a state of being brought into contact with each other.

A production method for a composite according to another aspect of the present application includes a first base material treatment step of subjecting a surface of a gallium oxide layer of a first base material to a nitridation treatment to functionalize the surface of the gallium oxide layer, where the first base material includes a gallium nitride layer and the gallium oxide layer which is formed and exposed on the gallium nitride layer; a second base material treatment step of subjecting a surface of a diamond layer of a second base material to an oxidation treatment to functionalize the surface of the diamond layer, where the second base material includes the diamond layer, the surface of which is a (100) plane; and a joining step of applying reaction energy to a contact part to join the first base material and the second base material while the surface of the gallium oxide layer that has undergone the first base material treatment step and the surface of the diamond layer that has undergone the second base material treatment step are in a state of being brought into contact with each other.

### BRIEF DESCRIPTION OF DRAWINGS

FIG. 1 A planar image of a composite 1 of Example 1, which was obtained by carrying out an observation from the diamond substrate side.

FIG. 2 A planar image of a composite 2 of Example 1, which was obtained by carrying out an observation from the GaN layer side.

FIG. 3 A planar image of a composite of Example 2, which was obtained by carrying out an observation from the diamond substrate side.

FIG. 4 A cross-sectional microscope image of the composite of Example 2.

FIG. 5 A transmission electron microscope image of the joining interface of the composite of Example 2.

FIG. 6 An energy dispersive X-ray spectroscopy spectrum of the intermediate layer of the composite of Example 2.

FIG. 7 A transmission electron microscope image and element maps in the vicinity of the joining interface of the composite of Example 2.

FIG. 8 Electron energy loss spectroscopy spectra of the intermediate layer of the composite of Example 2 and the diamond substrate.

FIG. 9 A planar image of an adhered body of Comparative Example 2, which was obtained by carrying out an observation from the diamond substrate side.

FIG. 10 A planar image of an adhered body of Comparative Example 3, which was obtained by carrying out an observation from the diamond substrate side.

FIG. 11 A planar image of a composite of Example 3, which was obtained by carrying out an observation from the diamond substrate side.

FIG. 12 A planar image of a composite of Example 4, which was obtained by carrying out an observation from the diamond wafer side.

FIG. 13 A rocking curve of a GaN substrate of the reference example.

FIG. 14 X-ray high electron spectroscopy spectra of the surface of the GaN layer before and after the reduction treatment in Example 2.

### DETAILED DESCRIPTION

The present application has been made in consideration of such circumstances, and an object of the present disclosure is to provide a production method for a composite that makes it possible to join GaN and diamond even in an atmospheric air while also suppressing the deterioration of crystallinity of the diamond and GaN, and a composite in which diamond having suppressed deterioration of crystallinity is joined to GaN having suppressed deterioration of crystallinity with an intermediate layer being interposed between the diamond and the GaN.

In the production method for a composite according to the present application, the gallium oxide layer on the gallium nitride layer and the diamond layer are each subjected to a predetermined treatment that suppresses deterioration of crystallinity, thereby being functionalized and joined. Therefore, according to the production method for a composite according to the present application, a composite in which a gallium nitride layer having suppressed deterioration of crystallinity and a diamond layer having suppressed deterioration of crystallinity are joined to each other can be obtained. In addition, in the composite according to the present application, the gallium nitride layer and the diamond layer are joined to each other with a predetermined intermediate layer being interposed therebetween. Therefore, according to the composite according to the present application, a composite in which a gallium nitride layer having suppressed deterioration of crystallinity and a diamond layer having suppressed deterioration of crystallinity are joined to each other can be obtained.

A composite according to the present embodiment includes a gallium nitride layer, an intermediate layer, and a diamond layer. The intermediate layer is formed on the surface of the gallium nitride layer. The diamond layer is joined to the surface of the gallium nitride layer with the intermediate layer being interposed between the diamond layer and the gallium nitride layer. More specifically, a second base material including the diamond layer is joined to a first base material containing the gallium nitride layer with the intermediate layer being interposed between the second base material and the first base material. The intermediate layer contains carbon, gallium, and oxygen. The intermediate layer may contain nitrogen. Examples of the first base material include various substrates such as a single crystal GaN substrate, a GaN/sapphire substrate having a GaN layer on a surface of a sapphire base material, a GaN/Si substrate having a GaN layer on a surface of a Si base material, and a GaN/SiC substrate having a GaN layer on a surface of a SiC base material.

A natural oxide film, which is a gallium oxide film, is formed on the surface of these GaN layers, and in the present embodiment, the intermediate layer is derived from this gallium oxide film. It is noted that the intermediate layer may be derived from a gallium oxide film other than the natural oxide film on the GaN layer. The fact that the intermediate layer contains gallium oxide can be determined by an energy dispersive X-ray analysis. In order to prevent a decrease in thermal conductivity between the gallium nitride layer and the diamond layer, the thickness of the intermediate layer is preferably 4 nm or less. Since the thickness of the natural oxide film formed on the surface of the GaN layer is about 2 nm, the thickness of the intermediate layer is often 2 nm or more.

In the semiconductor device disclosed in Patent Document 1, in which the natural oxide film is removed by a sputtering treatment in an ultra-high vacuum and joining is carried out, the nitrogen content is larger than the oxygen content at the joining interface between the GaN-based semiconductor and the diamond substrate. However, in a case where the natural oxide film is subjected to a sputtering treatment, the crystallinity of the GaN is deteriorated. In the present embodiment, the intermediate layer is derived from a gallium oxide film on the surface of the GaN layer. Therefore, the oxygen content of the intermediate layer is larger than the nitrogen content thereof. In this way, by joining the first base material and the second base material by interposing an intermediate layer containing carbon, gallium, and oxygen and having a nitrogen content smaller than the oxygen content, the shear strength between the first base material and the second base material is 0.1 MPa or more.

Examples of the second base material include various substrates such as a single crystal diamond substrate, a diamond/Si substrate having a diamond layer on a surface of a Si base material, and a diamond/sapphire substrate having a diamond layer on a surface of a sapphire base material. In addition, the diamond layer preferably has a surface which is a (100) plane or a (111) plane. In addition, the diamond layer may also be a mosaic crystal having a surface which is a (100) plane or a (111) plane.

A production method for a composite according to a first embodiment of the present application includes a first base material treatment step, a second base material treatment step, and a joining step. The first base material includes a gallium nitride layer, and a gallium oxide layer which is formed and exposed on the gallium nitride layer. In the first base material treatment step, the surface of the gallium oxide layer of the first base material is subjected to a predetermined treatment to functionalize the surface of the gallium oxide layer. The predetermined treatment is one or more of an oxidation treatment, a nitridation treatment, and a reduction treatment.

This oxidation treatment is a treatment in which oxygen atoms are introduced into the surface of the gallium oxide layer to grow the gallium oxide layer. This nitridation treatment is a treatment for introducing nitrogen atoms into the surface of the gallium oxide layer. This reduction treatment is a treatment for introducing reactive functional groups onto the surface while thinning the gallium oxide layer. Examples of the oxidation treatment include a treatment with a liquid containing ammonia and hydrogen peroxide and a treatment with reactive oxygen plasma. The nitridation treatment includes a treatment with reactive nitrogen plasma. The reduction treatment includes a treatment with hydrochloric acid. This treatment with hydrochloric acid allows the surface of the gallium oxide layer to be functionalized with one or more of an —OH group, an —NH₂ group, and a —Cl group.

The examples of these various treatments also apply to the second base material treatment step in the production method for a composite according to the first embodiment, and the first base material treatment step and the second base material treatment step in the production method for a composite according to the second embodiment. It is not necessarily clear what chemical structure the surface of the gallium oxide layer functionalized by the oxidation treatment or nitridation treatment in the first base material treatment step has. However, the surface of the functionalized gallium oxide layer has properties that make the surface of the functionalized gallium oxide layer easier to be joined to the surface of the diamond layer which has been functionalized in the second base material treatment step. Moreover, these predetermined treatments, which do not involve the total removal of the gallium oxide layer, suppress the deterioration of the crystallinity of the GaN layer.

The second base material includes a diamond layer, the surface of which is a (111) plane. In the second base material treatment step, the surface of the diamond layer of the second base material is subjected to an oxidation treatment to introduce oxygen atoms into the surface of the diamond layer, thereby functionalizing the surface of the diamond layer. In addition, C—O—C groups or —OH groups are formed on the surface of the diamond layer by the oxidation treatment. The functionalized surface of the diamond layer has properties that make the functionalized surface of the diamond layer easier to be joined to the surface of the gallium oxide layer which has been functionalized in the first base material treatment step.

In the joining step, reaction energy is applied to a contact part to join the first base material and the second base material while the surface of the gallium oxide layer that has undergone the first base material treatment step and the surface of the diamond layer that has undergone the second base material treatment step are in a state of being brought into contact with each other. The reaction energy includes thermal energy, light energy, electrical energy, chemical energy, or the like. In the present embodiment, the contact part between the first base material and the second base material is heated at a temperature of about 200° C.

The joining step joins the surfaces of the gallium oxide layer and the diamond layer to each other. According to the electron energy loss spectroscopy spectra of the gallium oxide layer and diamond layer after joining, it is considered that the gallium oxide layer and diamond layer are not joined by the formation of Ga—O—C bonds, but are joined by the diffusion of C atoms on the surface of the diamond layer into the gallium oxide layer. It is noted that although the joining step can be carried out in a vacuum container, it can also be carried out in the atmospheric air. Therefore, in the joining step according to the production method for a composite according to the present embodiment, a vacuum joining device is not required.

A production method for a composite according to a second embodiment of the present application will be described. In the description of the production method for a composite according to the present embodiment, parts that overlap with the production method for a composite according to the first embodiment will be omitted as appropriate. The production method for a composite according to the present embodiment also includes a first base material treatment step, a second base material treatment step, and a joining step. In the first base material treatment step, a surface of a gallium oxide layer of a first base material is subjected to a nitridation treatment to functionalize the surface of the gallium oxide layer, where the first base material includes a gallium nitride layer and the gallium oxide layer which is formed and exposed on the gallium nitride layer. In the second base material treatment step, a surface of a diamond layer of a second base material is subjected to an oxidation treatment to functionalize the surface of the diamond layer, where the second base material includes the diamond layer, the surface of which is a (100) plane.

A diamond whose surface is a (100) plane (hereinafter sometimes simply referred to as “(100) diamond”) is generally used in industry. However, the joining of the (100) diamond to GaN has been difficult. The inventors of the present application have found that by subjecting a gallium oxide layer on a gallium nitride layer to a nitridation treatment, rather than an oxidation and reduction treatment, the gallium oxide layer becomes easier to be joined to a (100) diamond surface that has been subjected to the oxidation treatment. In the joining step, in the same manner as in the joining step in the production method for a composite according to the first embodiment, reaction energy is applied to a contact part to join the first base material and the second base material while the surface of the gallium oxide layer that has undergone the first base material treatment step and the surface of the diamond layer that has undergone the second base material treatment step are in a state of being brought into contact with each other.

### EXAMPLES

### Example 1

A GaN/sapphire substrate (POWDEC K.K., thickness: 0.635 mm) having a GaN layer with a thickness of 2 μm on a surface of a sapphire base material, where the surface of the GaN layer was a (0001) plane and had been polished, was cut into a parallelogram shape in which one side was approximately 8 mm and one side adjacent thereto was approximately 7 mm. The surface of the GaN layer of this GaN/sapphire substrate was treated according to the following procedure. The surface of this GaN layer, that is, the natural oxide film layer of GaN, was immersed for 10 minutes in a treatment liquid having a liquid temperature of 75° C. and composed of 10 mL of 28% aqueous ammonia, 10 mL of 35% hydrogen peroxide water, and 50 mL of pure water. Thereafter, the surface of the GaN layer was washed with pure water for 5 minutes (oxidation treatment).

On the other hand, a surface of a diamond layer of a single crystal diamond substrate (EDP Corporation), which is 0.3 mm thick and 3 mm square and the surface of which is a (111) plane, was treated under the same conditions as in the surface treatment of the GaN layer (oxidation treatment). These oxidation treatments functionalized the surfaces of the GaN layer and the diamond layer, which made these surfaces have properties that make these surfaces easier to be joined to each other. The surface of the GaN layer and the surface of the diamond layer were left in contact in the atmospheric air for one day, and then heated at a temperature of 200° C. for 2 hours to obtain a composite 1 in which the GaN/sapphire substrate and the diamond substrate were joined to each other, that is, the GaN layer and the diamond layer were joined to each other.

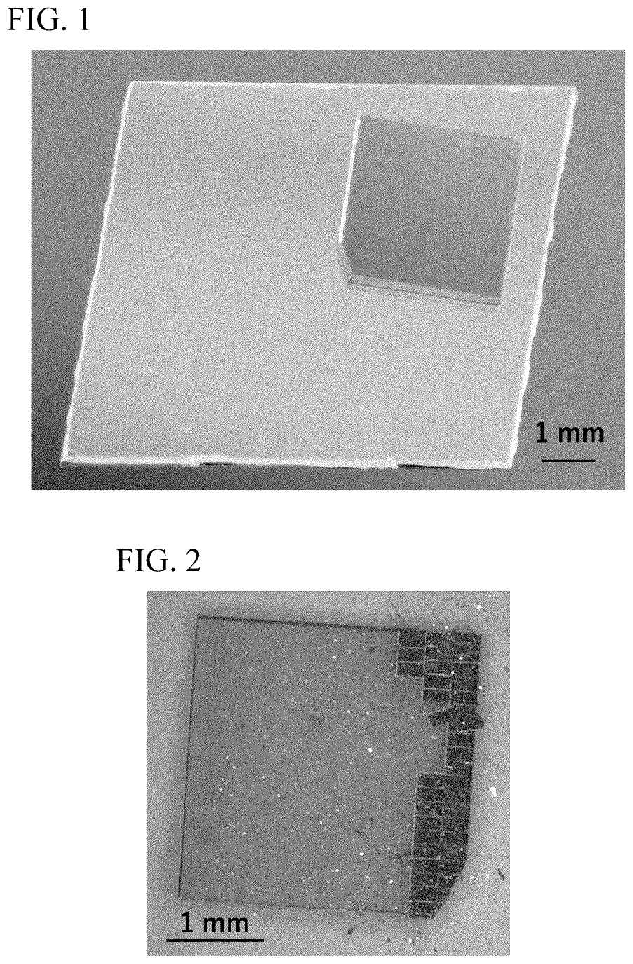

FIG. 1 shows a planar image of the composite 1 in a case of being observed from the diamond substrate side. As shown in FIG. 1, no bright portions indicative of depletion between the substrates were observed. That is, most of the surface of the GaN layer of the GaN/sapphire substrate and the surface of the diamond layer of the diamond substrate were joined to each other. From the side of the sapphire base material of the composite 1, irradiation was carried out with a laser beam having a wavelength of 248 nm and an energy density of 1,000 mJ/cm² in a 0.3 mm×0.15 mm lattice shape, the GaN layer was peeled off from the GaN/sapphire substrate to transfer it to the surface of the diamond layer of the diamond substrate, thereby obtaining a composite 2 in which the diamond layer was joined to the GaN layer. FIG. 2 show a planar image of the composite 2 in a case of being observed from the GaN layer side. As shown in FIG. 2, a plurality of rectangular GaN layers of 0.3 mm×0.15 mm were formed in a region of the right side of the surface of a 3 mm square diamond substrate. It is noted that the thickness of this GaN layer was 2 μm.

### Example 2

A GaN/Si substrate (CoorsTek GK, thickness: 0.635 mm) having a GaN layer with a thickness of 2 μm on a Si base material surface, where the surface of the GaN layer was a (0001) plane and had been polished, was cut into a 15 mm×16 mm rectangular shape. The surface of the GaN layer of this GaN/Si substrate was treated according to the following procedure. The surface of this GaN layer, that is, the natural oxide film layer of GaN, was immersed for 10 minutes in a treatment liquid having a liquid temperature of 70° C. and composed of 10 mL of 35% hydrochloric acid and 60 mL of pure water. Thereafter, the surface of this GaN layer was washed with pure water for 5 minutes (reduction treatment).

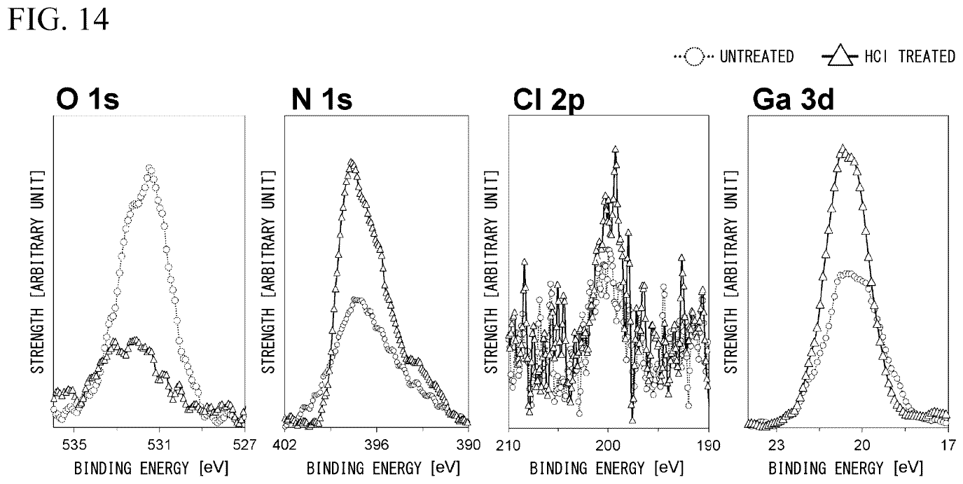

FIG. 14 shows the X-ray high electron spectroscopy spectra of the surface of the GaN layer after undergoing this reduction treatment (in the figure, “HCl treatment”) and the surface of the GaN layer before undergoing this reduction treatment (in the figure, “untreated”). As shown in FIG. 14, by treating the surface of the GaN layer with hydrochloric acid, the peak derived from the O1s orbital becomes smaller, and the position of this peak shifts to the higher energy side. It can be seen that by the reduction treatment of the surface of the GaN layer, the natural oxide film layer on the surface of the GaN layer was thinner, and Ga—OH, which has a higher bond energy than Ga₂O₃, was formed. Further, a peak in the vicinity of 397.7 eV, which is derived from the —NH₂ group, and a peak in the vicinity of 200 eV, which is derived from the —Cl group, became larger. It can be seen that Ga—NH₂ and Ga—Cl have been formed.

On the other hand, a surface-treated diamond substrate was obtained under the same conditions as in Example 1, except that the temperature of the treatment liquid during immersion was changed to 70° C. (oxidation treatment). It is known that C—O—C or C—OH is formed on the surface of the diamond layer that has been subjected to the oxidation treatment. Thereafter, a composite in which the GaN layer of the GaN/Si substrate and the diamond layer of the diamond substrate were joined to each other was obtained by the same method as in Example 1. This composite was obtained by a reaction, at the interface, between the —OH group, —NH₂ group, or —Cl group formed on the surface of the GaN layer and the C—O—C group or —OH group formed on the surface of the diamond layer.

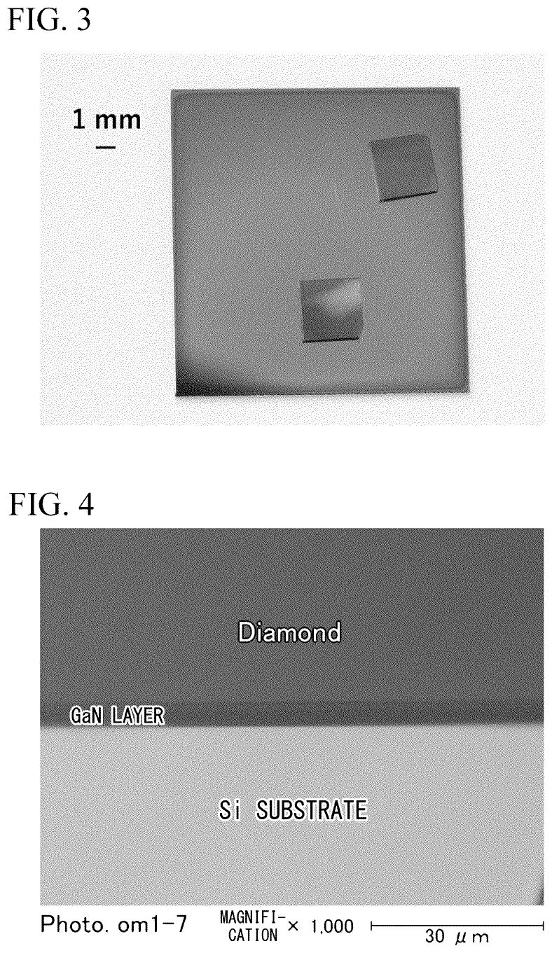

FIG. 3 shows a planar image of this composite in a case of being observed from the diamond substrate side. As shown in FIG. 3, in this composite, the surface of the diamond layer of two small diamond substrates is joined to a surface of a GaN layer of a large GaN/Si substrate. Even in a case where the GaN layer and the diamond layer overlap, Newton's rings are observed in a portion where the surface of the GaN layer and the surface of the diamond layer are not joined to each other. As shown in FIG. 3, the surface of the diamond layer of the diamond substrate at the top right was entirely joined to the surface of the GaN layer, and the surface of the diamond layer of the diamond substrate at the bottom center was joined to a region of about 70% of the surface of the GaN layer.

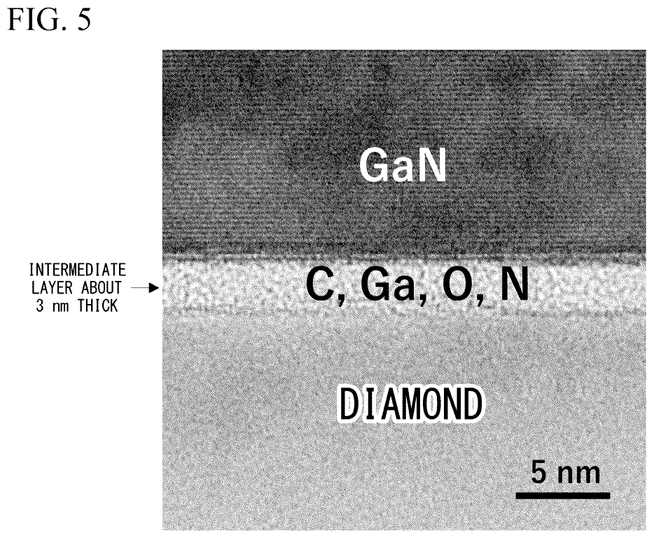

A laser beam was applied to cut the composite through the diamond substrate, the GaN layer, and the Si substrate. FIG. 4 shows a microscope image of this cross section. As shown in FIG. 4, the non-joined part was not observed at the joining interface between the diamond layer of the diamond substrate and the GaN layer. In addition, the composite was cut by irradiating it with a laser beam, and an extremely thin specimen was prepared by irradiating the cross section with a focused ion beam. The joining interface between the diamond layer and the GaN layer of this specimen was observed with a transmission electron microscope. FIG. 5 shows a transmission electron microscope image of this joining interface. As shown in FIG. 5, an intermediate layer having a thickness of about 3 nm was observed at the joining interface.

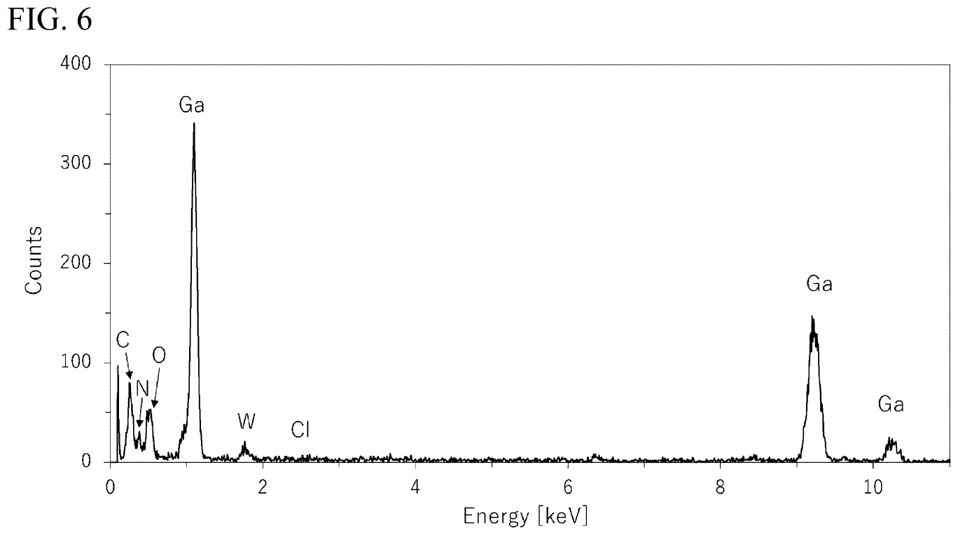

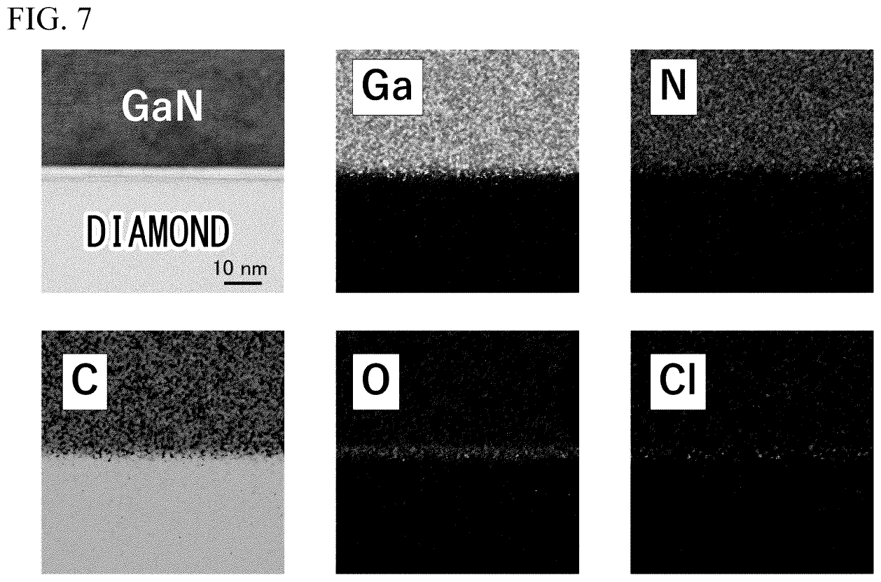

The composition of this intermediate layer was analyzed with energy dispersive X-ray spectroscopy. FIG. 6 shows the energy dispersive X-ray spectroscopy spectrum of this intermediate layer. The element ratio of this intermediate layer was C: 59.8%, Ga: 28.0%, O: 9.4%, N: 2.8%, and Cl: 0.1%, where the O content was larger than the N content. Further, the vicinity of the joining interface of this specimen was subjected to element mapping by energy dispersive X-ray spectroscopy. FIG. 7 shows a transmission electron microscope image in the vicinity of the joining interface of this specimen, and element maps of C, Ga, O, N, and Cl. The GaN layer portion was composed of Ga and N, the diamond layer portion was composed of C, and small amounts of O and Cl were observed at the joining interface.

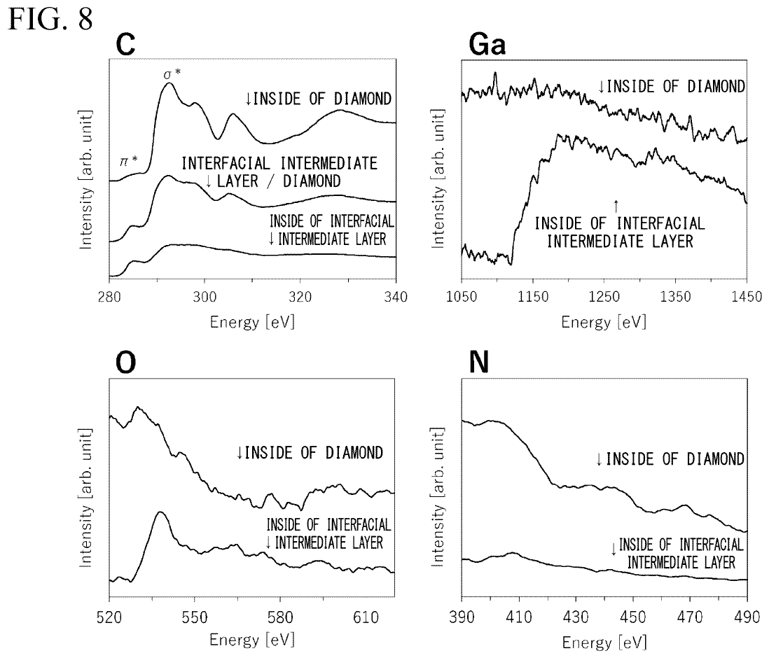

In addition, the structures of the intermediate layer and the diamond layer of this specimen were also evaluated by electron energy loss spectroscopy (EELS). FIG. 8 shows the electron energy loss spectra of the intermediate layer and the diamond layer of this specimen for C, Ga, O, and N. In a region where the crystallinity of diamond is high, a peak derived from the σ bond of carbon (sp³) is observed in the vicinity of 292 eV. A peak of the σ-bond was observed in the inside of the diamond layer of this specimen (in the figure, “inside of diamond”); however, a peak characteristic of a π-bond (sp²) in the vicinity of 286 eV was observed at the interface between the intermediate layer and the diamond layer (in the figure, “interface intermediate layer/diamond”). In addition, peaks of Ga and O were detected in the inside of the diamond layer and in the inside of the intermediate layer (in the figure, “inside of interface intermediate layer interior”), but no significant peak was detected for N. From these results, it is considered that the intermediate layer is composed of carbon of a sp² bond, gallium, and oxygen.

### Comparative Example 1

The surface of the GaN layer of the same GaN/sapphire substrate as in Example 1 and the surface of the diamond layer of the same single crystal diamond substrate as in Example 1 were washed for 5 minutes with each of acetone, ethanol, and pure water in this order. The washed surfaces of the GaN/sapphire substrate and the diamond substrate were kept in contact with each other in the atmospheric air for one day, and then heated at a temperature of 200° C. for two hours. However, the GaN layer of the GaN/sapphire substrate and the diamond layer of the single crystal diamond substrate were not joined to each other. This is considered to be because, unlike Example 1, the surface treatments with acetone, ethanol, and pure water, which do not correspond to the oxidation treatment, the nitridation treatment, and the reduction treatment, did not change the properties that make the surfaces of the GaN layer and the diamond substrate easier to be joined to each other.

### Comparative Example 2

The same GaN/sapphire substrate as in Example 1 was cut into a parallelogram shape in which one side was approximately 8 mm and one side adjacent thereto was approximately 7 mm. The surface of the GaN layer of this GaN/sapphire substrate was treated under the same conditions as those for the surface treatment of the GaN layer of the GaN/sapphire substrate in Example 2 (reduction treatment). On the other hand, a surface of a diamond layer of a single crystal diamond substrate (EDP Corporation), which is 0.3 mm thick and 5 mm square and the surface of which is a (100) plane, was treated under the same conditions as in the surface treatment of the diamond layer of the diamond substrate in Example 1 (oxidation treatment).

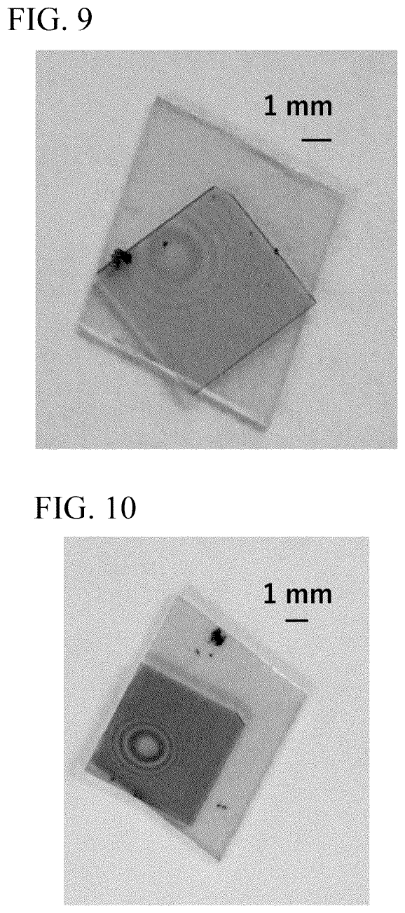

Thereafter, an adhered body in which the GaN layer of the GaN/sapphire substrate and the diamond layer of the diamond substrate were adhered to each other was obtained by the same method as in Example 1. FIG. 9 shows a planar image of this adhered body in a case of being observed from the diamond substrate side. As shown in FIG. 9, based on the fact that the depletion between the GaN/sapphire substrate and the diamond substrate was bright, and Newton's rings were observed, the GaN layer and the diamond layer were not joined entirely to each other in this adhered body.

### Comparative Example 3

The same GaN/sapphire substrate as in Example 1 was cut into a parallelogram shape in which one side was approximately 8 mm and one side adjacent thereto was approximately 7 mm. The surface of the GaN layer of this GaN/sapphire substrate was treated under the same conditions as those for the surface treatment of the GaN layer of the GaN/sapphire substrate in Example 1 (oxidation treatment). On the other hand, the surface of the diamond layer of the same diamond substrate as in Comparative Example 2 was subjected to a reactive ion etching treatment at an output of 200 W for 30 seconds by using oxygen gas at a pressure of 40 Pa (oxidation treatment).

Thereafter, an adhered body in which the GaN layer of the GaN/sapphire substrate and the diamond layer of the diamond substrate were adhered to each other was obtained by the same method as in Example 1. FIG. 10 shows a planar image of this adhered body in a case of being observed from the diamond substrate side. As shown in FIG. 10, based on the fact that the depletion between the GaN/sapphire substrate and the diamond substrate was bright, and Newton's rings were observed, the GaN layer and the diamond layer were not joined entirely to each other in this adhered body. In addition, this adhered body was broken in a case where a shear strength of 48 kPa was applied.

### Example 3

The same GaN/sapphire substrate as in Example 1 was cut into a parallelogram shape in which one side was approximately 8 mm and one side adjacent thereto was approximately 7 mm. The surface of the GaN layer of this GaN/sapphire substrate was treated under the same conditions as those for the surface treatment of the GaN layer of the GaN/sapphire substrate in Example 1. Further, the surface of this GaN layer was subjected to a reactive ion etching treatment at an output of 200 W for 30 seconds by using nitrogen gas at a pressure of 40 Pa (nitridation treatment). On the other hand, the surface of the diamond layer of the same diamond substrate as in Comparative Example 2 was treated under the same conditions as in the surface treatment of the diamond layer of the diamond substrate in Example 1 (oxidation treatment).

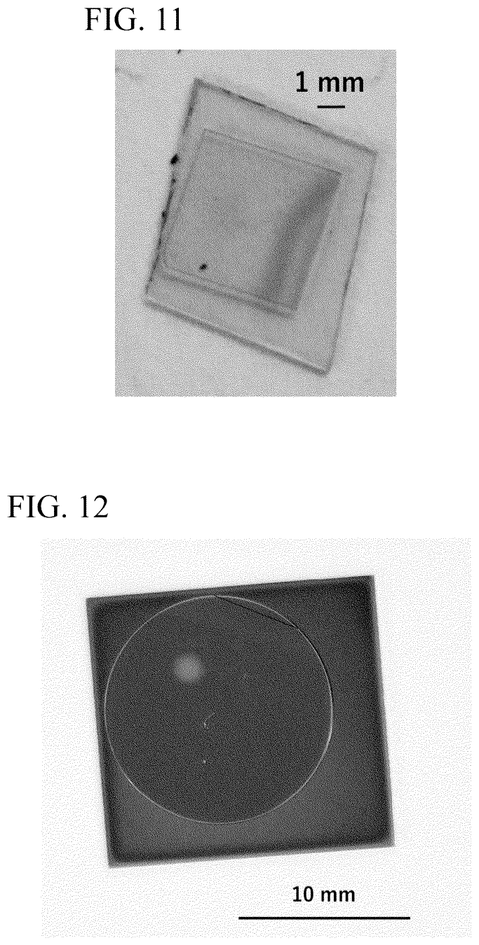

Thereafter, a composite in which the GaN layer of the GaN/sapphire substrate and the diamond layer of the diamond substrate were joined to each other was obtained by the same method as in Example 1. FIG. 11 shows a planar image of this composite in a case of being observed from the diamond substrate side. The darkness due to the depletion between the substrates was only observed in a part of the right side of the diamond substrate. That is, in this composite, the substrates, that is, the GaN layer and the diamond layer, were mostly joined to each other. This composite was broken in a case where a shear strength of 2.8 MPa was applied.

### Example 4

The same GaN/sapphire substrate as in Example 1 was cut into a 15 mm×16 mm rectangular shape. Thereafter, in the same manner as in Example 3, a GaN/sapphire substrate in which the surface of the GaN layer was subjected to a nitridation treatment was obtained. On the other hand, a surface of a diamond layer of a mosaic single crystal diamond minimal wafer (EDP Corporation), which has a circular shape of a thickness of 0.3 mm and a diameter of 12.5 mm and the surface of which is a (100) plane, was treated under the same conditions as in the surface treatment of the diamond layer of the diamond substrate in Example 1 (oxidation treatment).

Thereafter, a composite in which the GaN layer of the GaN/sapphire substrate and the diamond layer of the diamond wafer were joined to each other was obtained by the same method as in Example 1. FIG. 12 shows a planar image of this composite in a case of being observed from the diamond wafer side. The darkness due to the depletion between the substrate and the wafer was only observed in a part of the upper left side of the center of the diamond wafer. That is, in this composite, the GaN layer and the diamond layer were mostly joined to each other.

### Reference Example

The surface of the GaN layer of the same GaN/sapphire substrate as in Example 1 was irradiated for 120 seconds with a beam of Ar atoms accelerated at a voltage of 1.5 kV and a current of 100 mA to obtain a GaN substrate 1 from which the surface oxide film of the GaN layer had been removed by sputtering. In addition, a GaN substrate 2, in which the surface of the GaN layer was subjected to a reduction treatment in the same manner as in Example 2, was obtained. Further, a GaN substrate 3, in which the surface of the GaN layer was subjected to a nitridation treatment in the same manner as in Example 3, was obtained. The crystallinity of these GaN substrates was evaluated using XRD. That is, X-rays were made incident on the surface of each GaN substrate at an incident angle of 0.3°, and a peak derived from the GaN (110) plane in the vicinity of 2Θ=57.775 in a region about 8 nm away from this surface was evaluated.

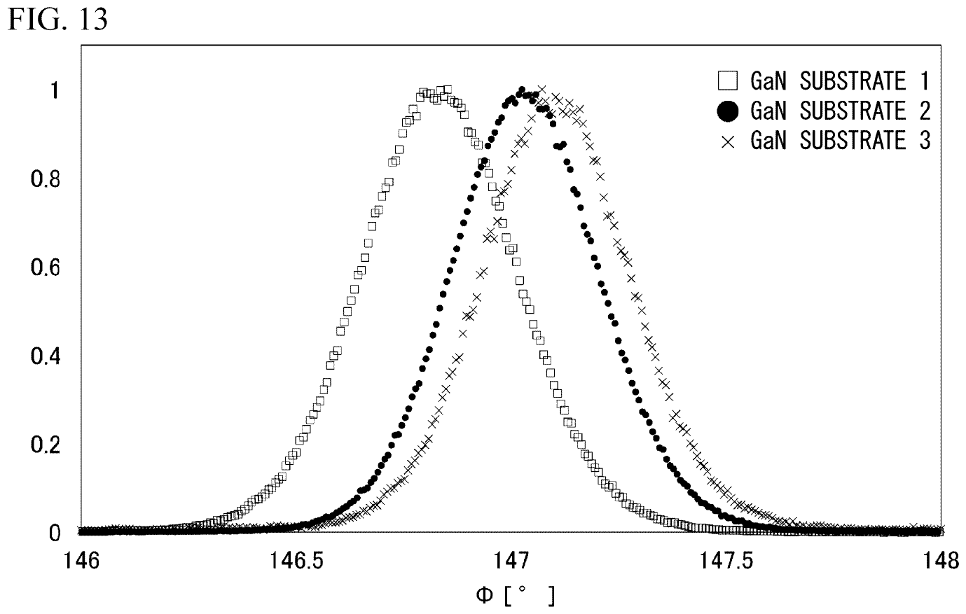

FIG. 13 shows the results of the rocking curve measurement of each GaN substrate by XRD. A larger half width means that the crystallinity of GaN is more deteriorated. In the GaN substrate 1, the half width from the in-plain XRD was 0.333°, and the half width from the rocking curve measurement was 0.418°. In addition, in the GaN substrate 2, the half width from the in-plain XRD was 0.331°, and the half width from the rocking curve measurement was 0.395°. Further, in the GaN substrate 3, the half width from the in-plain XRD was 0.330°, and the half width from the rocking curve measurement was 0.387°.

That is, in a case where the surface oxide film of the GaN layer was removed as in the case of the GaN substrate 1, the crystallinity of the surface of the GaN layer was significantly deteriorated. In contrast, in a case where the surface of the GaN layer was functionalized without completely removing the surface oxide film of the GaN layer, as in the GaN substrate 2 and GaN substrate 3, the deterioration of the crystallinity of the surface of the GaN layer could be suppressed. Therefore, it has been found that by subjecting the surface oxide film of the GaN layer to the oxidation treatment, nitridation treatment, and reduction treatment of the present application, it is possible to change the properties of the surface of the GaN layer to properties that make the surface of the GaN layer easier to be joined to the surface of the diamond layer while suppressing the deterioration of the crystallinity of the surface of the GaN layer.

1. A composite comprising:
a gallium nitride layer;
an intermediate layer that is formed on a surface of the gallium nitride layer and contains carbon, gallium, and oxygen; and
a diamond layer that is joined to the surface of the gallium nitride layer through the intermediate layer.

2. The composite according to claim 1, wherein the diamond layer has a surface which is a (100) plane or a (111) plane, or the diamond layer is a mosaic crystal having a surface which is a (100) plane or a (111) plane.

3. The composite according to claim 2, wherein the intermediate layer has a thickness of 4 nm or less.

4. The composite according to claim 3, wherein a nitrogen content of the intermediate layer is smaller than an oxygen content of the intermediate layer.

5. The composite according to claim 1,
wherein a second base material including the diamond layer is joined to a first base material containing the gallium nitride layer, and
a shear strength between the first base material and the second base material is 0.1 MPa or more.

6. A production method for a composite, comprising:
a first base material treatment step of subjecting a surface of a gallium oxide layer of a first base material to one or more of an oxidation treatment, a nitridation treatment, and a reduction treatment to functionalize the surface of the gallium oxide layer, where the first base material includes a gallium nitride layer and the gallium oxide layer which is formed and exposed on the gallium nitride layer;
a second base material treatment step of subjecting a surface of a diamond layer of a second base material to an oxidation treatment to functionalize the surface of the diamond layer, where the second base material includes the diamond layer, the surface of which is a (111) plane; and
a joining step of applying reaction energy to a contact part to join the first base material and the second base material while the surface of the gallium oxide layer that has undergone the first base material treatment step and the surface of the diamond layer which has undergone the second base material treatment step are in a state of being brought into contact with each other.

7. A production method for a composite, comprising:
a first base material treatment step of subjecting a surface of a gallium oxide layer of a first base material to a nitridation treatment to functionalize the surface of the gallium oxide layer, where the first base material includes a gallium nitride layer and the gallium oxide layer which is formed and exposed on the gallium nitride layer;
a second base material treatment step of subjecting a surface of a diamond layer of a second base material to an oxidation treatment to functionalize the surface of the diamond layer, where the second base material includes the diamond layer, the surface of which is a (100) plane; and
a joining step of applying reaction energy to a contact part to join the first base material and the second base material while the surface of the gallium oxide layer that has undergone the first base material treatment step and the surface of the diamond layer which has undergone the second base material treatment step are in a state of being brought into contact with each other.

8. The production method for a composite according to claim 6,
wherein in the first base material treatment step, an oxidation treatment is carried out, and
the oxidation treatment in the first base material treatment step is a treatment with a liquid containing ammonia and hydrogen peroxide.

9. The production method for a composite according to claim 6,
wherein in the first base material treatment step, a nitridation treatment is carried out, and
the nitridation treatment is a treatment with reactive nitrogen plasma.

10. The production method for a composite according to claim 6,
wherein in the first base material treatment step, a reduction treatment is carried out, and
the reduction treatment is a treatment with hydrochloric acid.

11. The production method for a composite according to claim 10, wherein in the first base material treatment step, the surface of the gallium oxide layer is functionalized with one or more of an —OH group, an —NH₂ group, and a —Cl group.

12. The production method for a composite according to claim 7, wherein the nitridation treatment is a treatment with reactive nitrogen plasma.

13. The production method for a composite according to claim 6, wherein the joining step is carried out in an atmospheric air.

14. The production method for a composite according to claim 7, wherein the joining step is carried out in an atmospheric air.
